(19) United States
(12) Patent Application Publication
(10) Pub. No.: US 2014/0168918 A1
(43) Pub. Date: Jun. 19, 2014

(54) FASTENING DEVICE FOR CIRCUIT BOARD

(71) Applicant: HON HAI PRECISION INDUSTRY CO., LTD., New Taipei (TW)

(72) Inventor: ZHENG-HENG SUN, New Taipei (TW)

(73) Assignee: HON HAI PRECISION INDUSTRY CO., LTD., New Taipei (TW)

(21) Appl. No.: 13/973,960

(22) Filed: Aug. 22, 2013

(30) Foreign Application Priority Data
Dec. 18, 2012 (CN) 2012105508923

(51) Int. Cl. H05K 7/14

(52) U.S. Cl. CPC H05K 7/1417
USPC 361/759

(57) ABSTRACT

A fastening device for a circuit board includes a chassis, two mounting members, and two fasteners. The chassis includes a side plate. The side plate defines two through holes. The mounting members are welded to the circuit board. Each mounting member defines a locking hole. The fasteners extend through the through holes and engage in the locking holes, thereby fastening the circuit board to the side plate. The side plate is perpendicular to the circuit board.

### BACKGROUND

1. Technical Field

The present disclosure relates to a fastening device for fastening a circuit board in place.

2. Description of Related Art

In a server, a circuit board is fastened to a chassis of the server. A plurality of screws extends through the circuit board and engages in a bottom plate of the chassis. Accordingly, a screwdriver is operated in the chassis. However, the operation of the screwdriver in the relatively small space of the chassis is inconvenient.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an exemplary embodiment of a fastening device together with a circuit board.

FIG. 2 is an assembled, isometric view of FIG. 1.

FIG. 3 is similar to FIG. 2, but viewed from another perspective.

FIG. 4 is a front plan view of FIG. 3.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean “at least one.”

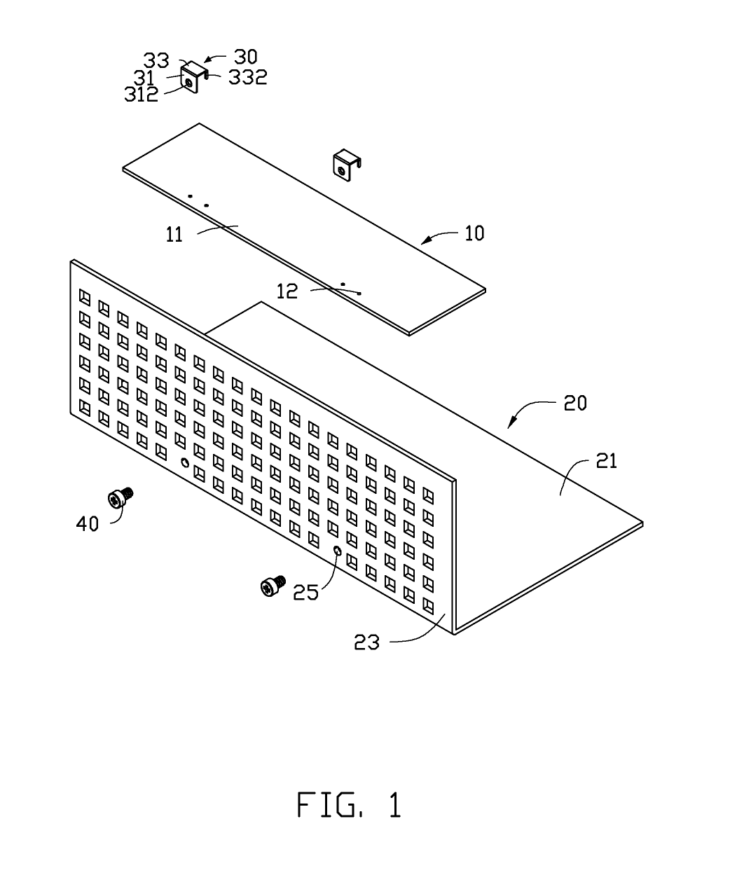

FIG. 1 shows an exemplary embodiment of a fastening device for a circuit board 10. The fastening device includes a chassis 20, two mounting members 30, and two fasteners 40. In the embodiment, the fasteners 40 are screws.

Two pairs of engaging holes 12 are defined in a side of the circuit board 10.

The chassis 20 includes a bottom plate 21, and a side plate 23 perpendicularly extending up from a side of the bottom plate 21. The side plate 23 defines two through holes 25 near the bottom plate 21.

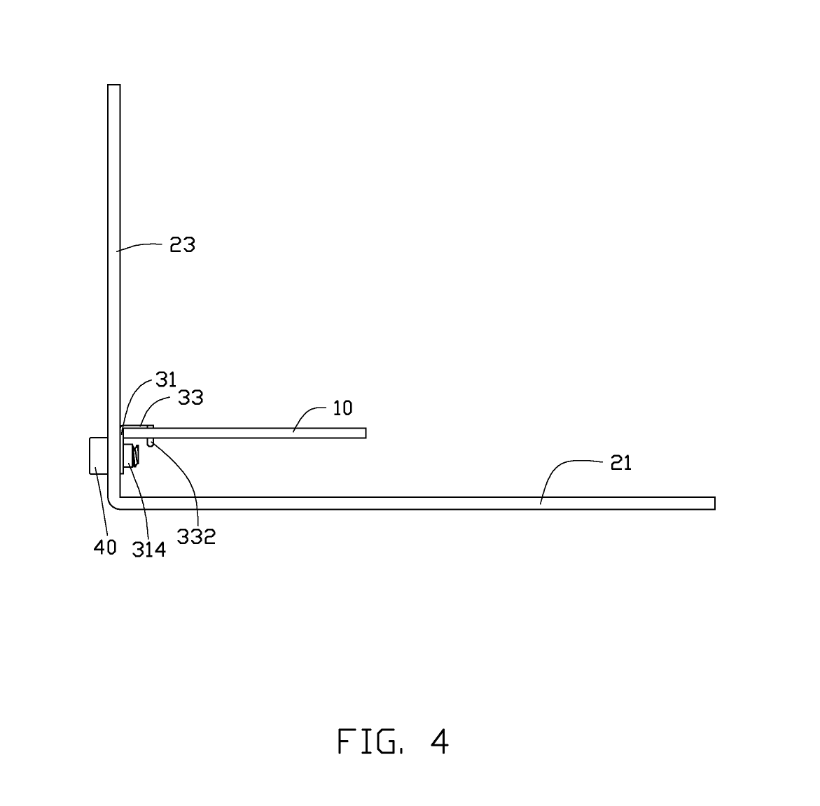

Each mounting member 30 includes a sidewall 31, and a top wall 33 perpendicularly extending from a top of the sidewall 31. A protrusion 314 (shown in FIG. 4) protrudes from an inner surface of the sidewall 31. A locking hole 312 is axially defined in the protrusion 314. A pair of pins 332 perpendicularly extends down from the top wall 33 and opposite to the sidewall 31.

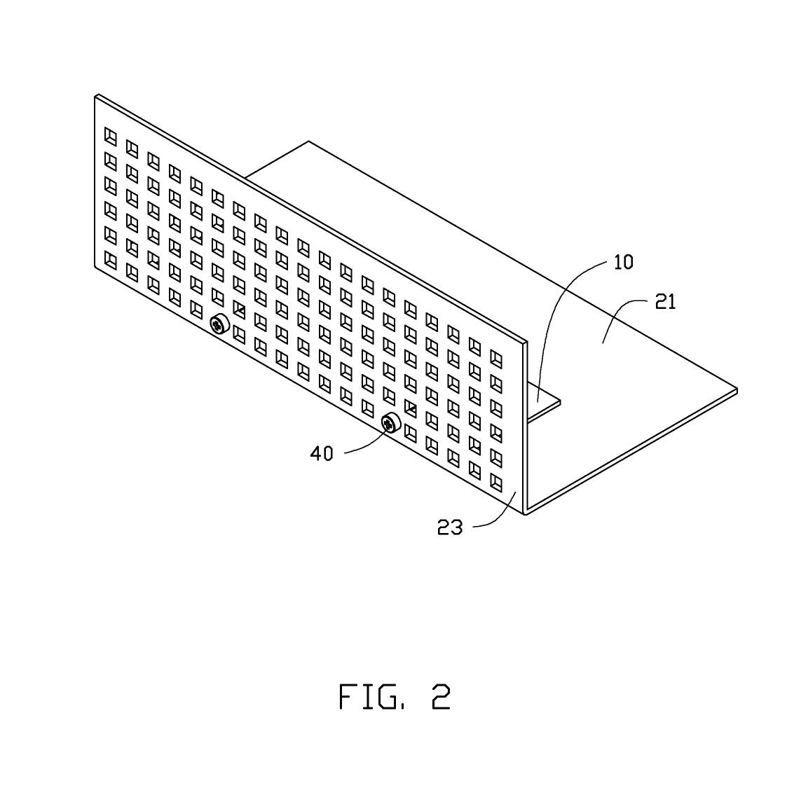

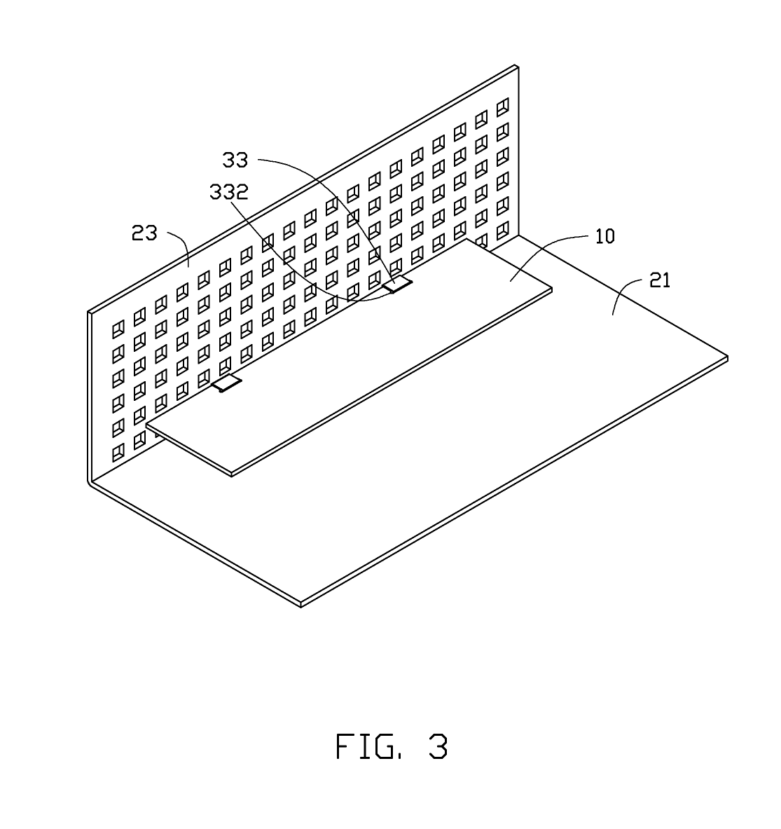

FIGS. 2-4 show in assembly, the pair of pins 332 of each mounting member 30 extends through the corresponding engaging holes 12. The top walls 33 are supported on a top surface of the circuit board 10. The pairs of pins 332 are welded to the circuit board 10. The sidewalls 31 abut against an inner surface of the side plate 23. The fasteners 40 extend through the through holes 25 and engage in the locking holes 312. Therefore, the circuit board 10 is fastened to the side plate 23, and is perpendicular to the side plate 23.

With the present arrangement the screwdriver is operated from outside of the chassis 20, by having the fasteners 40 extend through the side plate 23 and engage in the locking holes 312 of the mounting members 30, which is convenient.

Even though numerous characteristics and advantages of the embodiments have been set forth in the foregoing description, together with details of the structure and the functions of the embodiments, the disclosure is illustrative only, and changes may be made in details, especially in the matters of shape, size, and arrangement of parts within the principles of the embodiments to the full extent indicated by the broad general meaning of the terms in which the appended claims are expressed.

What is claimed is:

1. A fastening device for a circuit board, comprising:
a chassis comprising a side plate, the side plate defining two through holes;
two mounting members to be welded to the circuit board, each mounting member defining a locking hole; and
two fasteners;
wherein the fasteners extend through the through holes and engage in the locking holes, thereby fastening the circuit board to the side plate, the side plate is perpendicular to the circuit board.

2. The fastening device of claim 1, wherein each mounting member comprises a sidewall abutting against the side plate, and a top wall extending from the sidewall and supported on the circuit board.

3. The fastening device of claim 2, wherein a protrusion protrudes from each sidewall, the locking holes are axially defined in the protrusions.

4. The fastening device of claim 2, wherein a pin extends down from each top wall, and when fixing the two mounting members to the circuit board, the pins extend through a pair of engaging holes defined in the circuit board, the pins are welded to the circuit board.

5. The fastening device of claim 1, wherein the fasteners are screws.
